(19) United States
(12) Patent Application Publication
(10) Pub. No.: US 2023/0260798 A1
(43) Pub. Date: Aug. 17, 2023

(54) CHEMISTRY FOR HIGH ASPECT RATIO ETCH FOR 3D-NAND

(71) Applicant: Lam Research Corporation, Fremont, CA (US)

(72) Inventors: Nikhil Dole, Castro Valley, CA (US); Takumi Yanagawa, Fremont, CA (US)

(21) Appl. No.: 18/003,146

(22) PCT Filed: May 24, 2022
(86) PCT No.: PCT/US2022/030763

§ 371 Date: Dec. 22, 2022

Related U.S. Application Data
(60) Provisional application No. 63/202,044, filed on May 25, 2021.

(51) Int. Cl. H01L 21/311; H01L 21/3213; C09K 13/00

(52) U.S. Cl. CPC H01L 21/31116; H01L 21/31144; H01L 21/32137; H01L 21/32139; C09K 13/00

(57) ABSTRACT

Various embodiments herein relate to methods and apparatus for etching a memory hole in a stack of materials on a substrate. In some cases, the stack includes alternating layers of silicon oxide and silicon nitride. In other cases, the stack includes alternating layers of silicon oxide and polysilicon. In either case, three or more sets of processing conditions are used to etch the substrate. Various processing conditions such as the composition of a reactant mixture, pressure, substrate temperature, and/or plasma generation conditions are varied between the three or more sets of processing conditions to produce high quality etching results with high selectivity, a highly vertical etch profile, and a low degree of bowing.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

As semiconductor device dimensions continue to shrink, fabrication of such devices becomes increasingly difficult. One process commonly involved with semiconductor fabrication is the formation of recessed features on a semiconductor substrate. In many cases, the features are formed in dielectric material, and/or in a stack that includes dielectric material.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods and apparatus for etching a memory hole on a substrate. The memory hole may be etched in the context of 3D-NAND processing.

In one aspect of the disclosed embodiments, a method for etching a memory hole on a substrate is provided, the method including: (a) receiving the substrate in a processing chamber, the substrate including alternating layers of a first material and a second material provided in a stack, and a mask layer positioned over the stack, where the mask layer is patterned to include an opening where a recessed feature is to be etched in the stack, the recessed feature forming the memory hole; (b) generating a plasma in the processing chamber, exposing the substrate to the plasma, and etching the recessed feature into the stack at the opening in the mask layer using a first set of processing conditions, a second set of processing conditions, and a third set of processing conditions, where the first set of processing conditions provides a first reactant mixture to etch the recessed feature to a first depth, the second set of processing conditions provides a second reactant mixture to etch the recessed feature from the first depth to a second depth, and the third set of processing conditions provides a third reactant mixture to etch the recessed feature to a final depth; and (c) extinguishing the plasma and unloading the substrate from the processing chamber.

In a number of embodiments, the first material is silicon oxide and the second material is silicon nitride. The first depth may be between about 1-1.5 μm, and the second depth may be at least about 3 μm. In various embodiments, the first set of processing conditions provides: (i) the first reactant mixture having a first composition including CH₂F₂, O₂, and WF₆, (ii) a first plasma generation frequency between about 50-2,000 kHz, and (iii) a first plasma generation power density between about 18-64 W/cm² at the first plasma generation frequency. In these or other cases, the first composition may further include CHF₃, CH₃F, SF₆, and C₄F₈. In these or other cases, the first composition includes between about 15-40% CH₂F₂, by volume, excluding any inert gases in the first composition.

In various embodiments, the second set of processing conditions provides: (i) the second reactant mixture having a second composition including CH₂F₂, WF₆, SF₆, C₄F₈, and O₂, (ii) a second plasma generation frequency between about 50-2,000 kHz and a third plasma generation frequency between about 20-1000 MHz, and (iii) a second plasma generation power density between about 18-85 W/cm² at the second plasma generation frequency, and a third plasma generation power density between about 4.9-17 W/cm² at the third plasma generation frequency. In these or other embodiments, the second composition may further include CHF₃ and CH₃F. In these or other embodiments, the second composition may include between about 1-10% SF₆, by volume, excluding any inert gases in the second composition. In a number of embodiments, the second composition may cycle between composition 2A and composition 2B, where composition 2A has a higher concentration of C₄F₈ and CH₂F₂ compared to composition 2B, and where composition 2A has a lower concentration of O₂ compared to composition 2B.

In various embodiments, the third set of processing conditions provides: (i) the third reactant mixture having a third composition including CH₂F₂, WF₆, C₄F₈, and O₂, (ii) a fourth plasma generation frequency between about 50-2,000 kHz and a fifth plasma generation frequency between about 20-100 MHz, and (iii) a fourth plasma generation power density between about 18-64 W/cm² at the fourth plasma generation frequency, and a fifth plasma generation power density between about 4.9-12.2 W/cm² at the fifth plasma generation frequency. In these or other embodiments, the third composition may further include CHF₃ and CH₃F.

In various embodiments, the first set of processing conditions provides a first reactant mixture having a first composition, the second set of processing conditions provides a second reactant mixture having a second composition, and the third set of processing conditions provides a third reactant mixture having a third composition. The first, second, and third compositions may vary from one another in particular ways. For instance, in a number of embodiments, the first composition may have a higher concentration of CH₂F₂ compared to the second composition and the third composition. In these or other embodiments, the second composition may have a higher concentration of SF₆ than the first composition and the third composition. In these or other embodiments, the third composition may have a higher concentration of O₂ than the second composition.

In various embodiments, the first set of processing conditions may provide plasma generation using only a single plasma generation frequency between about 50-2,000 kHz. In these or other embodiments, the first, second, and third sets of processing conditions may each provide a processing pressure between about 15-45 mTorr. In these or other embodiments, the first, second, and third sets of processing conditions may each provide a substrate support temperature between about 30-80° C. In these or other embodiments, the third set of processing conditions may result in increasing a critical diameter at a bottom of the recessed feature.

In some cases, a ratio of C:H and/or a ratio of C:W may be controlled during one or more times. For instance, in some embodiments, at least one of the following conditions may be satisfied: (1) the first composition includes a ratio of C:H between about 0.1-3, (2) the second composition includes a ratio of C:H between about 0.1-3, and/or (3) the third composition includes a ratio of C:H between about 0.2-20. In these or other embodiments, at least one of the following conditions may be satisfied:(1) the first composition includes a ratio of C:W between about 0.1-0.5, (2) the second composition includes a ratio of C:W between about 0.1-5, and/or (3) the third composition includes a ratio of C:W between about 2-20.

In a number of embodiments, the first material is silicon oxide and the second material is polysilicon. In various embodiments, the first set of processing conditions may provide: (i) the first reactant mixture having a first composition including CH₃F, H₂, C₄F₈, COS, and WF₆, (ii) a first plasma generation frequency between about 50-2,000 kHz, and a second plasma generation frequency between about 20-100 MHz, and (iii) a first plasma generation power density between about 7-64 W/cm² at the first plasma generation frequency, and a second plasma generation power density between about 4.9-12.2 W/cm² at the second plasma generation frequency.

In these or other embodiments, the second set of processing conditions may provide (i) the second reactant mixture having a second composition including CF₃I, HBr, C₄F₆, CH₂F₂, H₂, and WF₆, (ii) a third plasma generation frequency between about 50-2,000 kHz and a fourth plasma generation frequency between about 20-100 MHz, and (iii) a third plasma generation power density between about 7-64 W/cm² at the third plasma generation frequency, and a fourth plasma generation power density between about 4.9-12.2 W/cm² at the fourth plasma generation frequency.

In these or other embodiments, the third set of processing conditions may provide: (i) the third reactant mixture having a third composition including CF₃I, HBr, C₄F₆, and CH₂F₂, (ii) a fifth plasma generation frequency between about 50-2,000 kHz and a sixth plasma generation frequency between about 20-100 MHz, and (iii) a fifth plasma generation power density between about 7-64 W/cm² at the fifth plasma generation frequency, and a sixth plasma generation power density between about 4.9-12.2 W/cm² at the sixth plasma generation frequency.

In various embodiments, the second set of processing conditions provides a processing pressure between about 15-50 mTorr, the third set of processing conditions provides a processing pressure between about 10-30 mTorr, and the processing pressure of the second set of processing conditions is higher than the processing pressure of the third set of processing conditions.

In various embodiments, the first set of processing conditions provides a first reactant mixture having a first composition, the second set of processing conditions provides a second reactant mixture having a second composition, and the third set of processing conditions provides a third reactant mixture having a third composition. In some such embodiments, the first composition may have a higher concentration of CH₃F, C₄F₈, and COS than the second composition and the third composition. In these or other embodiments, the second composition may have a higher concentration of CF₃I, HBr, C₄F₆ and CH₂F₂ than the first composition. In these or other embodiments, the first, second, and third sets of processing conditions each provide a substrate support temperature between about 20-60° C. In these or other embodiments, the third set of processing conditions may result in increasing a critical diameter at a bottom of the recessed feature.

In various embodiments, a ratio of C:H and/or a ratio of C:W may be controlled during etching. For example, in various embodiments, at least one of the following conditions is satisfied: (1) the first composition includes a ratio of C:H between about 0.2-20, (2) the second composition includes a ratio of C:H between about 0.2-20, and/or (3) the third composition includes a ratio of C:H between about 0.5-7. In these or other embodiments, at least one of the following conditions may be satisfied: (1) the first composition includes a ratio of C:W between about 2-20, (2) the second composition includes a ratio of C:W between about 0.2-20, and/or (3) the third composition includes a ratio of C:W between about 2-20.

In another aspect of the disclosed embodiments, an apparatus for etching a substrate is provided, the apparatus including: a processing chamber; an inlet to the processing chamber; an outlet to the processing chamber; a substrate support in the processing chamber, configured to support the substrate during etching; a plasma generator configured to produce a plasma in the processing chamber; and a controller configured to cause etching the substrate using any of the methods claimed or otherwise described herein.

These and other aspects are described further below with reference to the drawings.

### BRIEF DESCRIPTION OF THE DRAWINGS

FIGS. 1A and 1B depict a partially fabricated semiconductor device before and after an etching operation, respectively, according to certain embodiments.

FIGS. 1C and 1D illustrate a partially fabricated semiconductor device before and after an etching operation, respectively, according to certain embodiments.

FIGS. 2A and 2B are flowcharts describing methods of etching a substrate according to various embodiments.

FIGS. 3A-3C depict an etching apparatus according to various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### I. Context and Applications

Fabrication of certain semiconductor devices involves etching high aspect ratio features into one or more materials provided on a substrate. In order to etch the high aspect ratio features, the substrate is first prepared as desired for a particular application. This may involve depositing one or more layers of material onto the substrate. These layers of material include the layers in which the feature will be etched. In many cases, the layers of material include alternating layers of silicon oxide, silicon nitride, and/or polysilicon, as described further below. After the material is deposited on the substrate, a mask layer is deposited and then patterned on the substrate, for example using lithography or other methods. The patterned mask layer serves to define where the features are etched on the substrate. Notably, features will be etched in areas where the mask layer has been removed. By contrast, areas where the mask remains will be protected during the etch.

A feature is a recess in the surface of a substrate. Features can have many different shapes including, but not limited to, cylinders, ovals, rectangles, squares, other polygonal recesses, trenches, etc.

Aspect ratios are a comparison of the depth of a feature to the critical dimension of the feature (typically its width or diameter). For example, a cylinder having a depth of 2 μm and a width of 50 nm has an aspect ratio of 40:1, often stated more simply as 40. Since the feature may have a non-uniform critical dimension over the depth of the feature, the aspect ratio can vary depending on where it is measured. For instance, sometimes an etched cylinder may have a middle portion that is wider than the top and bottom portions. This wider middle section may be referred to as the bow. An aspect ratio measured based on the critical dimension at the top of the cylinder (i.e., the neck) would be higher than an aspect ratio measured based on the critical dimension at the wider middle/bow of the cylinder. As used herein, aspect ratios are measured based on the critical dimension proximate the opening of the feature, unless otherwise stated.

The embodiments herein are presented in the context of etching memory holes for forming a vertical NAND (e.g., VNAND, also referred to as 3D NAND) device. In such embodiments, the material being etched includes a stack of alternating materials. In one example where the semiconductor device is fabricated to include a recessed gate, the stack of materials being etched includes alternating layers of silicon oxide and silicon nitride. These alternating layers are commonly referred to as an ONON stack.

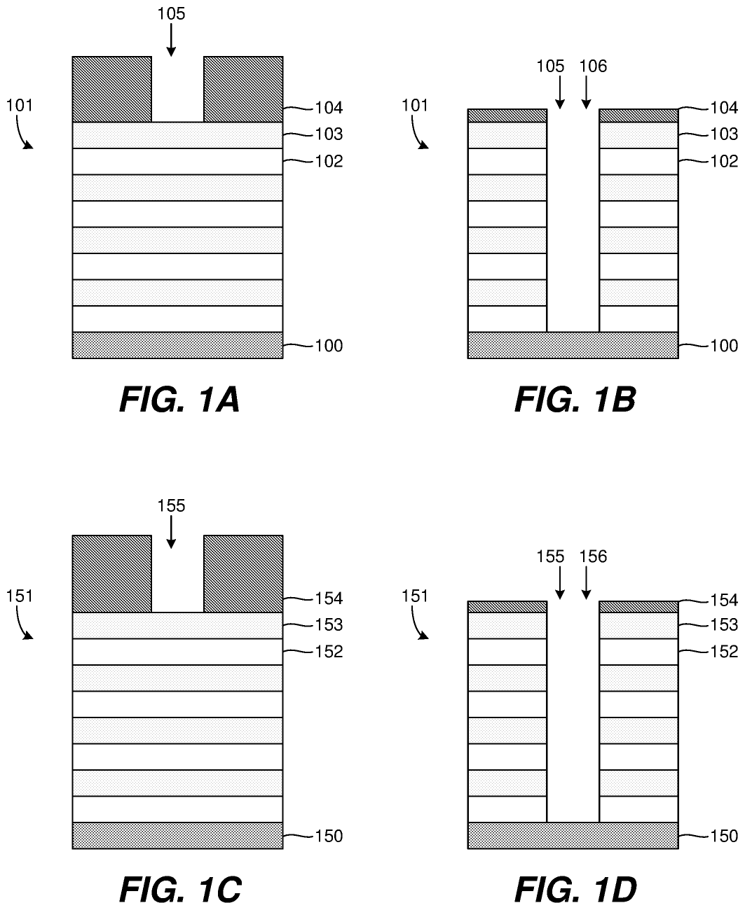

FIGS. 1A and 1B illustrate a substrate 101 having an ONON stack with alternating layers of silicon oxide 102 and silicon nitride 103. The individual layers of silicon oxide 102 and silicon nitride 103 may have thicknesses between about 20-50 nm, for example between about 30-40 nm. As device dimensions continue to decrease, such layers may be even thinner, e.g., below 20 nm. The ONON stack is positioned above underlying material 100. Underlying material 100 may include a variety of materials and structures as desired for a particular application. FIG. 1A shows the substrate 101 prior to etching. Mask layer 104 is patterned to include openings 105 where the features 106 are to be formed. The mask layer 104 is amorphous carbon, for example. Prior to etching, the mask layer 104 has a thickness between about 3-10 μm. FIG. 1B shows the substrate 101 after etching, with feature 106 formed at opening 105. The feature 106 may have a width/diameter between about 40-450 nm, for example between about 50-100 nm. The feature 106 may have a depth between about 2-15 μm, for example between about 5-12 μm. In various examples the etch depth may be at least about 3.4 μm, or at least about 3.8 μm. The feature 106 may have an aspect ratio between about 40-80. In some cases, the method may be performed twice, where a first mask layer is used during the first iteration, and a second mask layer is used during a second iteration, with approximately 5 μm depth being etched in each iteration. The etching process typically erodes the mask layer 104, such that the mask layer 104 is thinner (or no longer present) after etching, as compared to before etching.

In another example where the semiconductor device is fabricated to include a floating gate, the stack of materials being etched includes alternating layers of silicon oxide and polysilicon. These alternating layers are commonly referred to as an OPOP stack.

FIGS. 1C and 1D illustrate a substrate 151 having an OPOP stack with alternating layers of silicon oxide 152 and silicon nitride 153. The individual layers of silicon oxide 152 and polysilicon 153 may have thicknesses between about 20-50 nm, for example between about 30-40 nm. As device dimensions continue to decrease, such layers may be even thinner, e.g., below 20 nm. The OPOP stack is positioned above underlying material 150. Underlying material 150 may include a variety of materials and structures as desired for a particular application. FIG. 1C shows the substrate 151 prior to etching. Mask layer 154 is patterned to include openings 155 where the features 156 are to be formed. Mask layer 154 is amorphous carbon, for example. Prior to etching, the mask layer 154 has a thickness between about 3-10 μm. FIG. 1D shows the substrate 151 after etching, with feature 156 formed at opening 155. The feature 156 may have a width/diameter between about 40-450 nm, for example between about 50-100 nm. The feature 156 may have a depth between about 2-15 μm, for example between about 5-12 μm. In various examples the etch depth may be at least about 3.4 μm, or at least about 3.8 μm. The feature 106 may have an aspect ratio between about 30-60. As described in relation to FIGS. 1A and 1B, the mask layer 154 is partially or wholly consumed during etching, such that the mask layer 154 is thinner (or no longer present) after etching, as compared to before etching.

While FIGS. 1B and 1D only show a handful of layers being etched, this is merely for the purpose of illustration. It is understood that the number of layers being etched may be substantially greater, and that the aspect ratio of the final features may be substantially higher than what is shown in the figures.

Regardless of the materials present in the stack, there are several challenges to etching high aspect ratio features on semiconductor substrates. For example, as mentioned above, the mask layer is partially or wholly consumed during the etching process. This consumption limits the feature depth that can be achieved during the etch. This limitation can be countered by improving the selectivity of the etch process.

The etch selectivity for a particular etch process and set of materials can be defined numerically as: (the thickness etched through material A)/(the thickness etched through material B). For instance, an etch process that results in etching 2 μm of dielectric material and 0.5 μm of mask is understood to have an etch selectivity of 4 (e.g., 2 μm/0.5 μm=4), which may also be represented as an etch selectivity of 4:1. When the etch selectivity is not sufficiently high, the mask layer erodes away before the feature reaches its desired final depth. As such, one technique for increasing etch depth is to improve the etch selectivity. In this way, the mask layer erodes less quickly relative to the other materials being etched, and can be used to form deeper features.

Another problem that arises during etching of high aspect ratio features is a non-uniform etching profile. In other words, the features do not etch in a straight downward or vertical direction. Instead, the sidewalls of the features are often bowed such that a middle portion of the etched feature is wider (i.e., further laterally etched) than a top and/or bottom portion of the feature. This excessive lateral etching near the middle portion of the features can result in compromised structural and/or electronic integrity of the remaining material. The portion of the feature that bows outwards may occupy a relatively small portion of the total feature depth, or a relatively larger portion. The portion of the feature that bows outward is where the critical dimension of the feature is at its maximum. It is generally desirable for the maximum CD of the feature to be about the same as the CD elsewhere in the feature, for example at or near the bottom of the feature. Unfortunately, bow formation is seen even at aspect ratios as low as about 5.

Because of these and other limitations, conventional etching methods are, in practice, limited to forming relatively low aspect ratio features. However, some modern applications require cylinders or other recessed features having higher aspect ratios than those that can be achieved with conventional techniques.

One strategy for forming higher aspect ratio features is to deposit liners within the features. A liner is a sidewall passivation film that is formed in a deposition-only step. The deposition-only step may be performed after the features are partially etched, and may be cycled with the etch steps. In other words, liners do not form while the features are actively being etched. The liner acts to protect the sidewalls of the features, as well as the mask, from excessive etching during a subsequent etch step. Unfortunately, liners often produce a discontinuous etch profile just below the bottom of each liner, and in many cases result in the formation of striations (e.g., vertical grooves) within the recessed features.

Another strategy for forming higher aspect ratio features is to passivate the mask and/or feature sidewalls while the features are actively being etched. In a simple form, this passivation can be achieved with fluorocarbon-based polymer material, which may build up on feature sidewalls during etching. The fluorocarbon-based polymer material may form as a result of the interaction between the substrate materials and the etch chemistry (e.g., the fluorine- and carbon-containing etch chemistry such as CH₂F₂ and other similar fluorine- and carbon-containing etchants). However, such fluorocarbon-based polymers that form from existing etch chemistries have proven to be insufficient for forming high aspect ratio features with the desired vertical etch profile and other desired qualities.

The embodiments described herein utilize metal halide-based passivation chemistry (e.g., metal fluoride-based passivation chemistry including WF₆) in combination with particular processing conditions to form high aspect ratio features with desired qualities such as a high degree of etch selectivity, a strongly vertical profile, and a low degree of bowing. While many embodiments herein are presented in the context of chemistry that uses WF₆, in some cases other metal halides (e.g., metal fluorides, metal chlorides, metal bromides, etc.) may be used.

As mentioned above, the material into which the feature is etched may include one or more dielectric materials in various cases. Example dielectric materials include, but are not limited to, silicon oxides, silicon nitrides, silicon carbides, silicon carbo-nitrides, and laminates from any combination of these materials. Particular example materials include stoichiometric and non-stoichiometric formulations of SiO₂, SiN, SiC, SiCN, etc. The material or materials being etched may also include other elements, for example hydrogen, in various cases. In some embodiments, a nitride and/or oxide material being etched has a composition that includes hydrogen. As used herein, it is understood that silicon oxide materials, silicon nitride materials, etc. include both stoichiometric and non-stoichiometric versions of such materials, and that such materials may have other elements included, as described above. In certain embodiments, the material into which the feature is etched further includes polysilicon.

### II. Etching Process and Processing Conditions

In various embodiments, the etching process is a reactive ion etch process that involves flowing a chemical etchant into a reaction chamber (often through a showerhead), generating a plasma from, inter alia, the etchant and the metal halide passivation chemistry (e.g., WF₆ passivation chemistry or other metal halide passivation chemistry), and exposing a substrate to the plasma. The plasma dissociates the etchant compound(s) into neutral species and ion species (e.g., charged or neutral materials such as CF, CF₂ and CF₃). The plasma is a capacitively coupled plasma in many cases, though other types of plasma (e.g., inductively coupled plasma, microwave plasma, etc.) may be used as appropriate. Ions in the plasma are directed toward the substrate and cause the dielectric material to be etched away upon impact or through an ion induced chemical reaction.

Example apparatus that may be used to perform the etching process include the FLEX™ and VANTEX™ product families of reactive ion etch reactors available from Lam Research Corporation of Fremont, Calif. Appropriate apparatus are discussed further below.

As described above, issues related to etch selectivity and bow formation typically limit the maximum depth and aspect ratio that can be achieved when etching recessed features. However, the inventors have identified metal halide-based chemistry that may be used in combination with other processing conditions to enhance passivation of the feature sidewalls and mask region. Such chemistry and processing conditions may prevent excessive etching in the sidewall and mask regions, resulting in the formation of high aspect ratio features with high quality vertical etch profiles, even at significant feature depths.

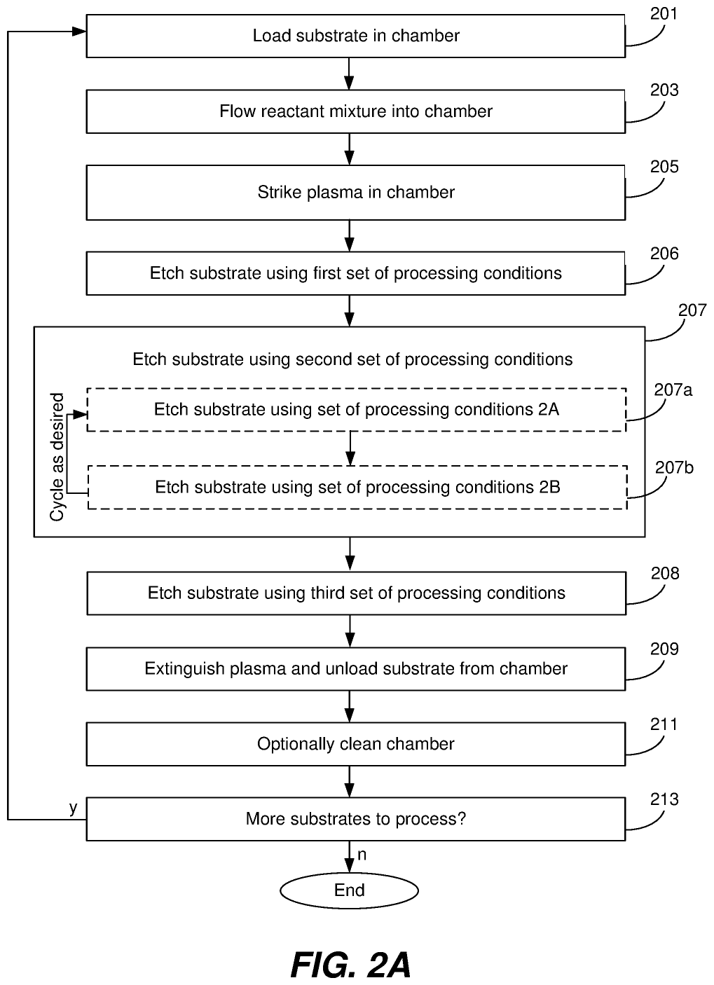

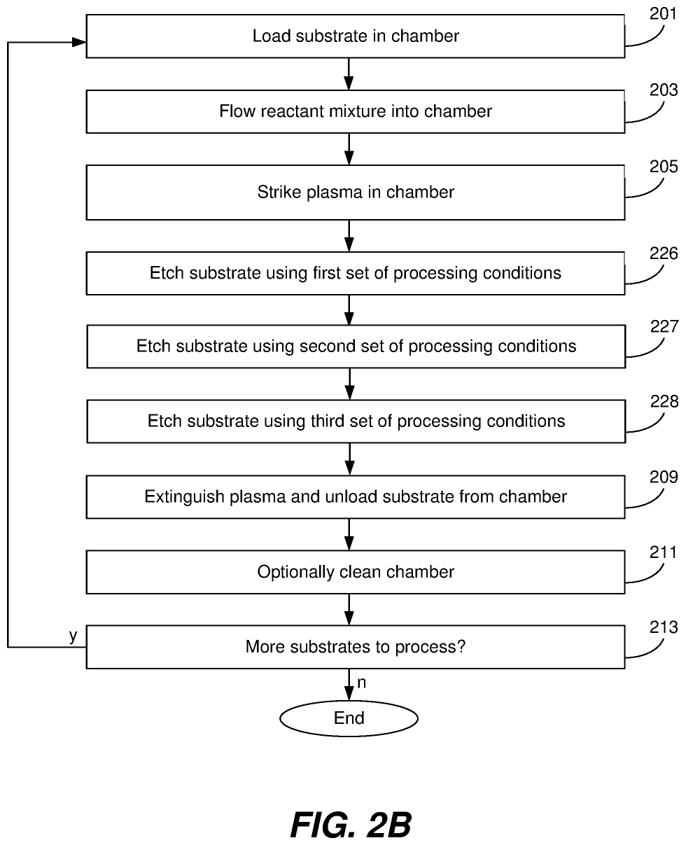

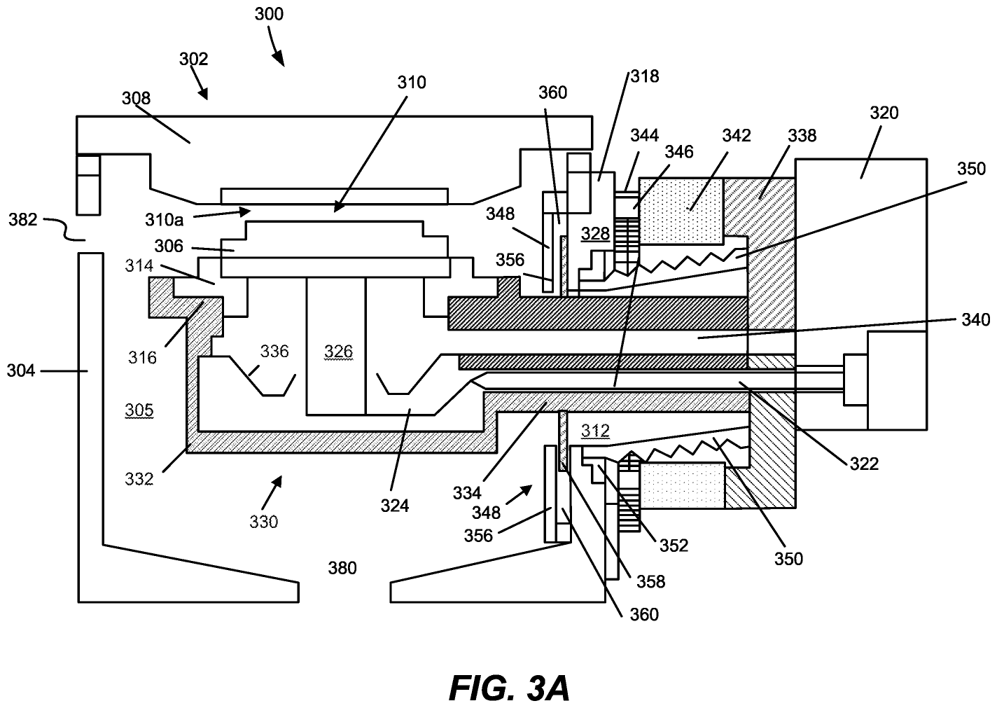

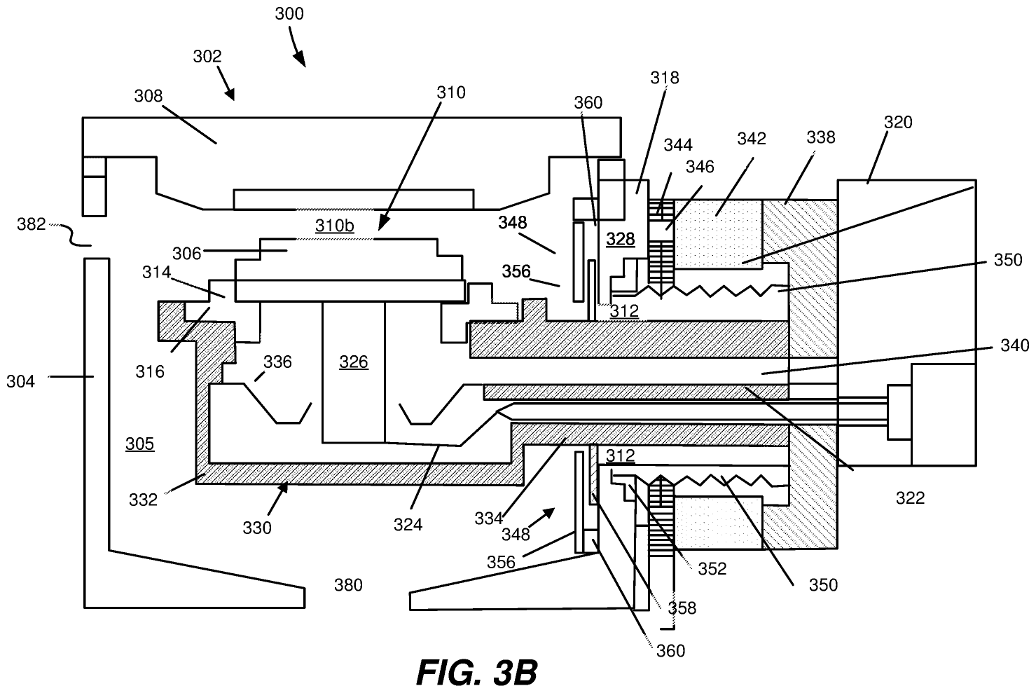

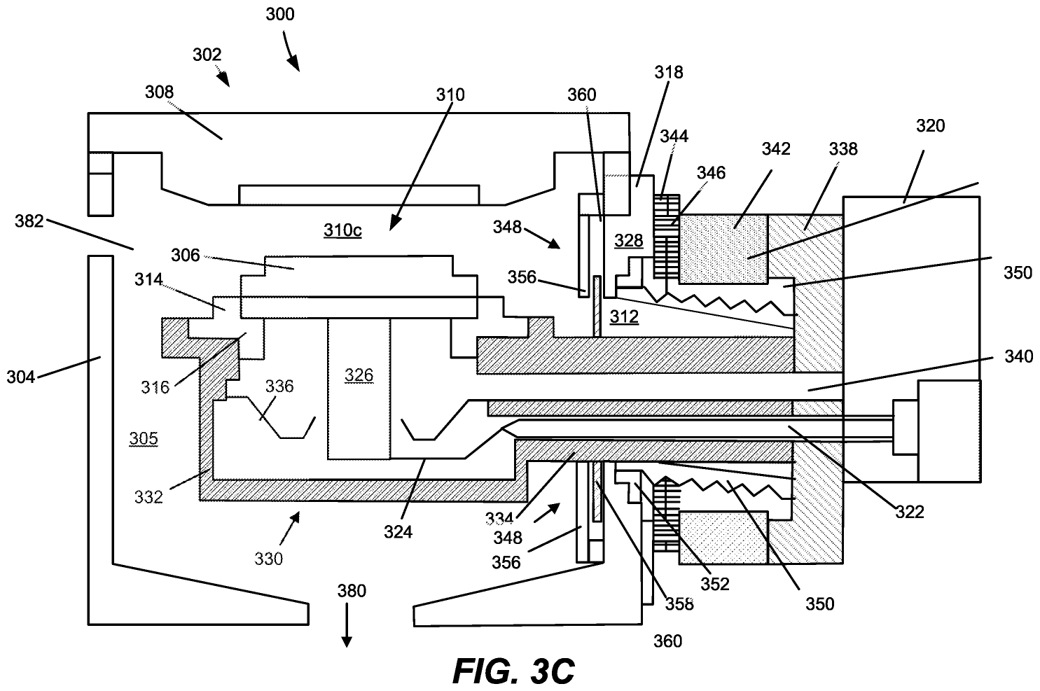

FIG. 2A presents a flowchart for a method of etching high aspect ratio recessed features according to various embodiments herein, for example where the layers being etched include an ONON stack, as described in relation to FIGS. 1A and 1B. The method begins at operation 201, where a substrate is loaded into a reaction chamber. One example reaction chamber is described below with reference to FIGS. 3A-3C. The substrate may be loaded into a substrate support such as an electrostatic chuck in some cases. The method continues with operation 203, where a reactant mixture is flowed into the chamber. The reactant mixture may include a variety of reactants and inert gas that may each serve one or more purpose. For instance, the reactant mixture includes etch chemistry, which is further discussed below. The reactant mixture also includes WF₆ and/or another metal halide, which acts as passivation chemistry. The composition of the reactant mixture changes over time, as discussed further below.

Next, at operation 205, plasma is struck in the chamber. The plasma is typically a capacitively coupled plasma, though other types of plasma may also be used. Because the composition of the reactant mixture changes over time, the composition of the plasma changes over time in a similar way.

Next, the substrate is etched in operations 206, 207, and 208, with a first set of processing conditions used during operation 206, a second set of processing conditions used during operation 207, and a third set of processing conditions used during operation 208. As indicated in FIG. 2A, operation 207 may be split into two operations 207a and 207b. Where this is the case, the second set of processing conditions may include two individual sets of processing conditions 2A and 2B, and these sets of processing conditions may be optionally cycled with one another. The various sets of processing conditions may be optimized based on a number of considerations, including but not limited to the instantaneous depth of the feature being etched. Example sets of processing conditions related to particular embodiments are discussed further below. As noted above, the composition of the reactant mixture and plasma change over time, for example providing different compositions for operations 206, 207a, 207b, and 208. The plasma may or may not be extinguished between operations 206-208. The substrate may be etched via ions and/or radicals in the plasma. The metal halide (e.g., WF₆) passivation chemistry present in the plasma operates to passivate the feature sidewalls and mask region, thus preventing these regions from becoming excessively etched as the features are etched to their final depth.

Next, at operation 209, the plasma is extinguished and the substrate is unloaded from the chamber. The substrate may be subjected to further processing after removal from the reaction chamber. For example, the substrate may be transferred to an ashing reactor, where any remaining mask material may be removed from the substrate in an ashing procedure. At operation 211, the reaction chamber may be optionally cleaned. The cleaning may occur while there is no substrate present. The cleaning may involve, e.g., exposing chamber surfaces to cleaning chemistry, which may be provided in the form of plasma. At operation 213, it is determined whether there are additional substrates to process. If so, the method repeats from operation 201 on a new substrate. Otherwise, the method is complete.

The operations shown in FIG. 2A do not necessarily occur in the order shown. Some operations may overlap in time, and some operations may occur at earlier or later times compared to what is shown in the figure.

With reference to FIGS. 1A and 1B, one embodiment relates to etching recessed features in an ONON stack, for example in the context of forming a semiconductor device that includes a recessed gate. In such embodiments, various processing conditions may be controlled as described herein. With reference to operation 206 of FIG. 2A, the first set of processing conditions provides a first reactant mixture having a first composition. The first composition is rich in CH₂F₂ (e.g., as compared to the second and third compositions, discussed further below). For instance, the flow rate of CH₂F₂ is between about 20-150 sccm. In addition, the metal halide (e.g., WF₆) is provided at a flow rate between about 0.25-5 sccm. Further, CHF₃ is provided at a flow rate between about 20-150 sccm, CH₃F is provided at a flow rate between about 20-150 sccm, SF₆ is provided at a flow rate between about 2-5 sccm, C₄F₈ is provided at a flow rate between about 30-100 sccm, and O₂ is provided at a flow rate between about 40-120 sccm. As mentioned, the first composition is rich in CH₂F₂. For example, the first composition may be between about 15-40% CH₂F₂, excluding any inert gases in the first reactant mixture. This percentage is calculated based on the standardized volumetric flow rates (e.g., sccm) of the non-inert species present in the first reactant mixture. The first reactant mixture has an atomic ratio of C:H that is between about 0.1-3. The first reactant mixture has an atomic ratio of C:W that is between about 0.1-0.5.

The first set of processing conditions generates the plasma at a single frequency of between about 50-2,000 kHz, for example about 400 kHz, using a power between about 13-60 kW. The power levels recited herein are appropriate for processing substrates having a diameter of about 300 mm and a surface area of about 707 cm², and can be scaled linearly based on substrate surface area. As such, this power level relates to a power density between about 18-64 W/cm². The first set of processing conditions provides a pressure between about 15-45 mTorr. The temperature of the substrate can be controlled indirectly by controlling the temperature of a substrate support on which the substrate is positioned during etching. The first set of processing conditions provides a substrate support temperature between about 30-80° C. The first set of processing conditions is used during an initial portion of the etching process, for example while the feature is being etched to a depth of about 1 to 1.5 μm.

With reference to operation 207 of FIG. 2A, the second set of processing conditions provides a second reactant mixture having a second composition. As described further below in relation to operations 207a and 207b, the second reactant mixture may include two distinct compositions that are cycled with one another. The second composition is rich in SF₆ (e.g., as compared to the first composition and third composition).

In cases where the second set of processing conditions includes only a single set of processing conditions, the following conditions are used. The flow rate of SF₆ is between about 1-10 sccm. In addition, the metal halide (e.g., WF₆) is provided at a flow rate between about 0.25-5 sccm. Further, CHF₃ is provided at a flow rate between about 20-180 sccm, CH₃F is provided at a flow rate between about 20-180 sccm, CH₂F₂ is provided at a flow rate between about 20-180 sccm, C₄F₈ is provided at a flow rate between about 10-100 sccm, and O₂ is provided at a flow rate between about 5-50 sccm. As mentioned, the second composition is rich in SF₆. For example, the second composition may be between about 1-10% SF₆, excluding any inert gases in the second reactant mixture. This percentage is calculated based on the standardized volumetric flow rates (e.g., sccm) of the non-inert species present in the second reactant mixture. The second reactant mixture has an atomic ratio of C:H that is between about 0.1-3. The second reactant mixture has an atomic ratio of C:W that is between about 0.1-5.

In cases where the second set of processing conditions includes two distinct sets of processing conditions 2A and 2B, the following conditions are used. In 2A, the flow rate of SF₆ is between about 0-20 sccm, the flow rate of the metal halide (e.g., WF₆) is between about 0.25-5 sccm, the flow rate of CHF₃ is between about 20-180 sccm, the flow rate of CH₃F is between about 20-180 sccm, the flow rate of CH₂F₂ is between about 20-180 sccm, the flow rate of C₄F₈ is between about 10-100 sccm, and the flow rate of O₂ is between about 10-150 sccm. In 2A, the second reactant mixture has an atomic ratio of C:H that is between about 0.1-3, and has an atomic ratio of C:W that is between about 0.1-5. In 2B, the flow rate of SF₆ is between about 0-3 sccm, the flow rate of the metal halide (e.g., WF₆) is between about 0.25-5 sccm, the flow rate of CHF₃ is between about 20-180 sccm, the flow rate of CH₃F is between about 20-180 sccm, the flow rate of CH₂F₂ is between about 20-180 sccm, the flow rate of C₄F₈ is between about 10-100 sccm, and the flow rate of O₂ is between about 10-150 sccm. In 2B, the second reactant mixture has an atomic ratio of C:H that is between about 0.1-3, and has an atomic ratio of C:W that is between about 3-15. Generally speaking, the processing conditions in 2A may provide higher C₄F₈, higher CH₂F₂, and lower O₂ flow, as compared to the processing conditions in 2B. Alternatively or in addition, the processing conditions in 2A may provide a greater flow of SF₆ and/or a lower ratio of C:W, as compared to the processing conditions in 2B.

The second set of processing conditions generates the plasma at a dual frequency, with a first frequency (e.g., a low frequency) between about 50-2,000 kHz, for example about 400 kHz, and a second frequency (e.g., a high frequency) between about 20-100 MHz, for example about 60 MHz. The lower frequency (e.g., 400 kHz or similar) is provided at a power between about 13-60 kW. This power level relates to a power density between about 18-85 W/cm². The higher frequency (e.g., 60 MHz or similar) is provided at a power between about 3.5-12 kW. This power level relates to a power density between about 4.9-17 W/cm². The second set of processing conditions provides a pressure between about 15-30 mTorr. The second set of processing conditions provides a substrate support temperature between about 40-80° C. The second set of processing conditions is used during a second portion of the etching process, for example while the features are being etched from a starting depth of about 1-1.5 μm to an ending depth of about at least 3 μm, for example about 5 μm.

With reference to operation 208 of FIG. 2A, the third set of processing conditions provides a third reactant mixture having a third composition. For instance, the flow rate of SF₆ is between about 0-1 sccm, the flow rate of the metal halide (e.g., WF₆) is between about 0.25-10 sccm, the flow rate of CHF₃ is between about 20-150 sccm, the flow rate of CH₃F is between about 20-150 sccm, the flow rate of CH₂F₂ is between about 20-150 sccm, the flow rate of C₄F₈ is between about 20-120 sccm, and the flow rate of O₂ is between about 40-120 sccm. The flow rate of O₂ for the third set of processing conditions may be at least about 10-15% greater than the flow rate of O₂ for the second set of processing conditions. The third composition may be between about 10-15% O₂, excluding any inert gases in the third reactant mixture. This percentage is calculated based on the standardized volumetric flow rates (e.g., sccm) of the non-inert species present in the third reactant mixture. The third reactant mixture has an atomic ratio of C:H that is between about 0.2-20. The third reactant mixture has an atomic ratio of C:W that is between about 2-20.

The third set of processing conditions generates the plasma at a dual frequency, with a first frequency (e.g., a low frequency) between about 50-2,000 kHz, for example about 400 kHz, and a second frequency (e.g., a high frequency) between about 20-100 MHz, for example about 60 MHz. The lower frequency (e.g., 400 kHz or similar) is provided at a power between about 13-45 kW. This power level relates to a power density between about 18-64 W/cm². The higher frequency (e.g., 60 MHz or similar) is provided at a power between about 3.5-8.6 kW. This power level relates to a power density between about 4.9-12.2 W/cm². The third set of processing conditions provides a pressure between about 15-30 mTorr. The third set of processing conditions provides a substrate support temperature between about 40-80° C. The pressure and substrate support temperature may be uniform or different between the different sets of processing conditions. The third set of processing conditions is used during a third portion of the etching process, for example while the features are being “overetched” and the critical diameter at the bottom of the feature is being widened/opened.

With reference to FIG. 2A, the substrate may be exposed to plasma in operations 205-208 for a duration between about 30-90 minutes.

FIG. 2B presents a flowchart for a method of etching high aspect ratio recessed features according to various embodiments herein, for example where the layers being etched include an OPOP stack, as described in relation to FIGS. 1C and 1D. The method of FIG. 2B is similar to the method of FIG. 2A, and for the sake of brevity, only the differences will be discussed in detail. Details related to operations 201-205 and 209-213 are discussed in relation to FIG. 2A.

In the embodiment of FIG. 2B, three different sets of processing conditions are used to etch the substrate, with a first set of processing conditions used in operation 226, a second set of processing conditions used in operation 227, and a third set of processing conditions used in operation 228. These sets of processing conditions may be optimized based on various considerations, including but not limited to the instantaneous depth of the feature being etched. Example sets of processing conditions are discussed below. The plasma may or may not be extinguished between operations 226-228. After the substrate is etched using the third set of processing conditions, the method of FIG. 2B continues in a similar manner to the method of FIG. 2A.

With reference to FIGS. 1C and 1D, one embodiment relates to etching recessed features in an OPOP stack, for example in the context of forming a semiconductor device that includes a floating gate. With reference to operation 226 of FIG. 2B, the first set of processing conditions provides a first reactant mixture having a first composition. For example, the flow rate of CH₃F is between about 20-150 sccm, the flow rate of H₂ is between about 20-120 sccm, the flow rate of C₄F₈ is between about 20-120 sccm, the flow rate of COS is between about 2-40 sccm, and the flow rate of the metal halide (e.g., WF₆) is between about 0.2-10 sccm. As compared to the second and third reactant mixtures, the first reactant mixture may have a higher flowrate/concentration of CH₃F, C₄F₈, and COS. The first reactant mixture has an atomic ratio of C:H that is between about 0.2-20. The first reactant mixture has an atomic ratio of C:W that is between about 2-20.

The first set of processing conditions generates the plasma at a dual frequency, with a first frequency (e.g., a low frequency) between about 50-2000 kHz, for example about 400 kHz, and a second frequency (e.g., a high frequency) between about 20-100 MHz, for example about 60 MHz. The plasma is generated at the first frequency using a power between about 5-45 kW (e.g., about 7-64 W/cm²), and at the second frequency using a power between about 3.5-8.6 kW (e.g., about 4.9-12.2 W/cm²). The first set of processing conditions provides a pressure between about 15-50 mTorr. The temperature of the substrate can be controlled indirectly by controlling the temperature of a substrate support on which the substrate is positioned during etching. The first set of processing conditions provides a substrate support temperature between about 20-60° C. The first set of processing conditions is used during an initial portion of the etching process, for example while the feature is being etched to a depth of about 1 to 1.5 μm.

With reference to operation 227 of FIG. 2B, the second set of processing conditions provides a second reactant mixture having a second composition. As compared to the first reactant mixture, the second reactant mixture has a greater amount of CF₃I, HBr, C₄F₆, and CH₂F₂, and a lower amount of CH₃F, C₄F₈, and COS. For instance, the flow rate of CF₃I is between about 10-50 sccm. The flow rate of HBr is between about 2-30 sccm. The flow rate of C₄F₆ is between about 10-150 sccm. The flow rate of CH₂F₂ is between about 20-150 sccm. Further, the flow rate of the metal halide (e.g., WF₆) is between about 0.1-4 sccm. The second reactant mixture has an atomic ratio of C:H that is between about 0.2-20. The second reactant mixture has an atomic ratio of C:W that is between about 0.2-20.

The second set of processing conditions generates the plasma at a dual frequency, with a first frequency (e.g., a low frequency) between about 50-2,000 kHz, for example about 400 kHz, and a second frequency (e.g., a high frequency) between about 20-100 MHz for example about 60 MHz. The lower frequency (e.g., 400 kHz or similar) is provided at a power between about 5-45 kW. This power level relates to a power density between about 7-64 W/cm². The higher frequency (e.g., 60 MHz or similar) is provided at a power between about 3.5-8.6 kW. This power level relates to a power density between about 4.9-12.2 W/cm². The second set of processing conditions provides a pressure between about 15-50 mTorr. The second set of processing conditions provides a substrate support temperature between about 20-60° C. The second set of processing conditions is provided during a second portion of the etching process, for example while the features are being etched from a depth of about 1.5 μm to a depth of about 5 μm.

With reference to operation 228 of FIG. 2B, the third set of processing conditions provides a third reactant mixture having a third composition. As compared to the first reactant mixture, the third reactant mixture has a greater amount of CF₃I, HBr, C₄F₆, and CH₂F₂, and a lower amount of CH₃F, C₄F₈, and COS. The third reactant mixture may be the same as the second reactant mixture. For instance, the flow rate of CF₃I is between about 10-50 sccm. The flow rate of HBr is between about 2-30 sccm. The flow rate of C₄F₆ is between about 10-150 sccm. The flow rate of CH₂F₂ is between about 20-150 sccm. The third reactant mixture has an atomic ratio of C:H that is between about 0.5-7. The third reactant mixture has an atomic ratio of C:W that is between about 2-20.

The third set of processing conditions generates the plasma at a dual frequency, with a first frequency (e.g., a low frequency) between about 50-2,000 kHz, for example about 400 kHz, and a second frequency (e.g., a high frequency) between about 20-100 MHz, for example about 60 MHz. The lower frequency (e.g., 400 kHz or similar) is provided at a power between about 5-45 kW. This power level relates to a power density between about 7-64 W/cm². The higher frequency (e.g., 60 MHz or similar) is provided at a power between about 3.5-8.6 kW. This power level relates to a power density between about 4.9-12.2 W/cm². The third set of processing conditions provides a pressure between about 10-30 mTorr. As compared to the second set of processing conditions, the third set of processing conditions provides a lower pressure. The third set of processing conditions provides a substrate support temperature between about 10-60° C. The third set of processing conditions is provided during a third portion of the etching process, for example while the features are being “overetched” and the critical diameter at the bottom of the feature is being widened/opened. Over the course of etching the substrate in operations 226-228, the substrate is exposed to plasma for a duration between about 2000-5000 seconds. The first, second, and third sets of processing conditions may provide a uniform substrate support temperature.

Various sets of processing conditions listed above recite particular ranges for the ratio of C:H and C:W in the relevant reactant mixture. Controlling these ratios allows for tuning of the selectivity and bow control. If these ratios are not appropriately controlled, it can lead to etch stop and capping, which are undesirable. Similarly, failure to appropriately control the substrate temperature can lead to these same problems.

The use of the metal halide (e.g., WF₆) in a reactant mixture for etching, in combination with the various processing conditions described herein, promotes high quality etching results with strongly vertical etch profile, low bowing, and a high degree of etch selectivity. This allows for formation of deep, high aspect ratio features, without having to scale the mask layer to an unacceptably high thickness. The various processing conditions within each set of processing conditions are balanced against one another to produce particular processing environments, as needed for a relevant portion of a given etching process. Further, the different sets of processing conditions for a particular embodiment are balanced against one another to produce the desired high quality etching results. The interplay of chemistry, temperature, pressure, and plasma conditions yield superior results that could not be achieved by conventional etching methods.

The embodiments described herein provide a 20-25% improvement in selectivity compared to conventional etching methods. Without wishing to be bound by theory or mechanism of action, it is believed that the metal halide (e.g., WF₆), when provided in combination with the disclosed processing conditions, increases the rate at which the stack of materials is etched, without compromising (e.g., without increasing) the rate at which the mask layer is etched. As a result, selectivity is improved. Further, it is believed that the metal halide, when provided in combination with the disclosed processing conditions, passivates the sidewalls of the partially etched features, thereby preventing undesirable bow growth and producing a high quality vertical etch profile.

### Apparatus

The methods described herein may be performed by any appropriate apparatus. In various embodiments, an appropriate apparatus includes a processing chamber configured for plasma processing, and a controller configured to perform any of the methods described herein. As mentioned above, example apparatus that may be used to perform the etching processes described herein include the FLEX™ and VANTEX™ product families of reactive ion etch reactors available from Lam Research Corporation of Fremont, Calif.

FIGS. 3A-3C illustrate an embodiment of an adjustable gap capacitively coupled confined RF plasma reactor 300 that may be used for performing the etching operations described herein. As depicted, a vacuum chamber 302 includes a chamber housing 304, surrounding an interior space housing a lower electrode 306. In an upper portion of the chamber 302 an upper electrode 308 is vertically spaced apart from the lower electrode 306. Planar surfaces of the upper and lower electrodes 308, 306 are substantially parallel and orthogonal to the vertical direction between the electrodes. Preferably the upper and lower electrodes 308, 306 are circular and coaxial with respect to a vertical axis. A lower surface of the upper electrode 308 faces an upper surface of the lower electrode 306. The spaced apart facing electrode surfaces define an adjustable gap 310 therebetween. During operation, the lower electrode 306 is supplied RF power by an RF power supply (match) 320. RF power is supplied to the lower electrode 306 though an RF supply conduit 322, an RF strap 324 and an RF power member 326. A grounding shield 336 may surround the RF power member 326 to provide a more uniform RF field to the lower electrode 306. As described in commonly-owned U.S. Pat. No. 7,732,728, the entire contents of which are herein incorporated by reference, a wafer is inserted through wafer port 382 and supported in the gap 310 on the lower electrode 306 for processing, a process gas is supplied to the gap 310 and excited into plasma state by the RF power. The upper electrode 308 can be powered or grounded.

In cases where one or more species delivered to the plasma reactor 300 is stored as a liquid, a modified gas delivery system (not shown) may be used. For instance, the modified gas delivery system may include hardware (e.g., bubbler, vaporizer, etc.) for vaporizing a liquid phase species, as well as appropriate plumbing (e.g., high temperature gas lines and valves) and control equipment (e.g., high temperature mass flow controller and/or liquid flow controller) for implementing the reactant delivery.

In the embodiment shown in FIGS. 3A-3C, the lower electrode 306 is supported on a lower electrode support plate 316. An insulator ring 314 interposed between the lower electrode 306 and the lower electrode Support plate 316 insulates the lower electrode 306 from the support plate 316.

An RF bias housing 330 supports the lower electrode 306 on an RF bias housing bowl 332. The bowl 332 is connected through an opening in a chamber wall plate 318 to a conduit support plate 338 by an arm 334 of the RF bias housing 330. In a preferred embodiment, the RF bias housing bowl 332 and RF bias housing arm 334 are integrally formed as one component, however, the arm 334 and bowl 332 can also be two separate components bolted or joined together.

The RF bias housing arm 334 includes one or more hollow passages for passing RF power and facilities, such as gas coolant, liquid coolant, RF energy, cables for lift pin control, electrical monitoring and actuating signals from outside the vacuum chamber 302 to inside the vacuum chamber 302 at a space on the backside of the lower electrode 306. The RF supply conduit 322 is insulated from the RF bias housing arm 334, the RF bias housing arm 334 providing a return path for RF power to the RF power supply 320. A facilities conduit 340 provides a passageway for facility components. Further details of the facility components are described in U.S. Pat. Nos. 5,948,704 and 7,732,728 and are not shown here for simplicity of description. The gap 310 is preferably surrounded by a confinement ring assembly or shroud (not shown), details of which can be found in commonly owned published U.S. Pat. No. 7,740,736 herein incorporated by reference. The interior of the vacuum chamber 302 is maintained at a low pressure by connection to a vacuum pump through vacuum portal 380.

The conduit support plate 338 is attached to an actuation mechanism 342. Details of an actuation mechanism are described in commonly-owned U.S. Pat. No. 7,732,728 incorporated herein by above. The actuation mechanism 342, such as a servo mechanical motor, stepper motor or the like is attached to a vertical linear bearing 344, for example, by a screw gear 346 such as a ball screw and motor for rotating the ball screw. During operation to adjust the size of the gap 310, the actuation mechanism 342 travels along the vertical linear bearing 344. FIG. 3A illustrates the arrangement when the actuation mechanism 342 is at a high position on the linear bearing 344 resulting in a small gap 310 a. FIG. 3B illustrates the arrangement when the actuation mechanism 342 is at a mid position on the linear bearing 344. As shown, the lower electrode 306, the RF bias housing 330, the conduit support plate 338, the RF power supply 320 have all moved lower with respect to the chamber housing 304 and the upper electrode 308, resulting in a medium size gap 310 b.

FIG. 3C illustrates a large gap 310 c when the actuation mechanism 342 is at a low position on the linear bearing. Preferably, the upper and lower electrodes 308, 306 remain co-axial during the gap adjustment and the facing surfaces of the upper and lower electrodes across the gap remain parallel.

This embodiment allows the gap 310 between the lower and upper electrodes 306, 308 in the CCP chamber 302 during multi-step process recipes (BARC, HARC, and STRIP etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 306, 308.

FIG. 3A illustrates laterally deflected bellows 350 sealed at a proximate end to the conduit support plate 338 and at a distal end to a stepped flange 328 of chamber wall plate 318. The inner diameter of the stepped flange defines an opening 312 in the chamber wall plate 318 through which the RF bias housing arm 334 passes. The distal end of the bellows 350 is clamped by a clamp ring 352.

The laterally deflected bellows 350 provides a vacuum seal while allowing vertical movement of the RF bias housing 330, conduit support plate 338 and actuation mechanism 342. The RF bias housing 330, conduit support plate 338 and actuation mechanism 342 can be referred to as a cantilever assembly. Preferably, the RF power supply 320 moves with the cantilever assembly and can be attached to the conduit support plate 338. FIG. 3B shows the bellows 350 in a neutral position when the cantilever assembly is at a mid position. FIG. 3C shows the bellows 350 laterally deflected when the cantilever assembly is at a low position.

A labyrinth seal 348 provides a particle barrier between the bellows 350 and the interior of the plasma processing chamber housing 304. A fixed shield 356 is immovably attached to the inside inner wall of the chamber housing 304 at the chamber wall plate 318 so as to provide a labyrinth groove 360 (slot) in which a movable shield plate 358 moves vertically to accommodate vertical movement of the cantilever assembly. The outer portion of the movable shield plate 358 remains in the slot at all vertical positions of the lower electrode 306.

In the embodiment shown, the labyrinth seal 348 includes a fixed shield 356 attached to an inner surface of the chamber wall plate 318 at a periphery of the opening 312 in the chamber wall plate 318 defining a labyrinth groove 360. The movable shield plate 358 is attached and extends radially from the RF bias housing arm 334 where the arm 334 passes through the opening 312 in the chamber wall plate 318. The movable shield plate 358 extends into the labyrinth groove 360 while spaced apart from the fixed shield 356 by a first gap and spaced apart from the interior surface of the chamber wall plate 318 by a second gap allowing the cantilevered assembly to move vertically. The labyrinth seal 348 blocks migration of particles spalled from the bellows 350 from entering the vacuum chamber interior 305 and blocks radicals from process gas plasma from migrating to the bellows 350 where the radicals can form deposits which are subsequently spalled.

FIG. 3A shows the movable shield plate 358 at a higher position in the labyrinth groove 360 above the RF bias housing arm 334 when the cantilevered assembly is in a high position (small gap 310 a). FIG. 3C shows the movable shield plate 358 at a lower position in the labyrinth groove 360 above the RF bias housing arm 334 when the cantilevered assembly is in a low position (large gap 310 c). FIG. 3B shows the movable shield plate 358 in a neutral or mid position within the labyrinth groove 360 when the cantilevered assembly is in a mid position (medium gap 310 b). While the labyrinth seal 348 is shown as symmetrical about the RF bias housing arm 334, in other embodiments the labyrinth seal 348 may be asymmetrical about the RF bias arm 334.

The apparatus shown in FIGS. 3A-3C includes a controller that is configured to perform the methods described herein. In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for etching a memory hole on a substrate, the method comprising:
(a) receiving the substrate in a processing chamber, the substrate comprising alternating layers of a first material and a second material provided in a stack, and a mask layer positioned over the stack, wherein the mask layer is patterned to include an opening where a recessed feature is to be etched in the stack, the recessed feature forming the memory hole;
(b) generating a plasma in the processing chamber, exposing the substrate to the plasma, and etching the recessed feature into the stack at the opening in the mask layer using a first set of processing conditions, a second set of processing conditions, and a third set of processing conditions,
wherein the first set of processing conditions provides a first reactant mixture to etch the recessed feature to a first depth,
wherein the second set of processing conditions provides a second reactant mixture to etch the recessed feature from the first depth to a second depth,
wherein the third set of processing conditions provides a third reactant mixture to etch the recessed feature to a final depth, wherein at least one of the first reactant mixture, second reactant mixture, and third reactant mixture comprises a metal halide; and
(c) extinguishing the plasma and unloading the substrate from the processing chamber.

2. The method of claim 1, wherein the first material is silicon oxide and the second material is silicon nitride.

3. The method of claim 1, wherein the first depth is between about 1-1.5 μm, and the second depth is at least about 3 μm.

4. The method of claim 2, wherein the first set of processing conditions provides:
(i) the first reactant mixture having a first composition comprising CH₂F₂, O₂, and WF₆, (ii) a first plasma generation frequency between about 50-2,000 kHz, and (iii) a first plasma generation power density between about 18-64 W/cm² at the first plasma generation frequency.

5. The method of claim 4, wherein the first composition further comprises CHF₃, CH₃F, SF₆, and C₄F₈.

6. The method of claim 4, wherein the first composition comprises between about 15-40% CH₂F₂, by volume, excluding any inert gases in the first composition.

7. The method of claim 2, wherein the second set of processing conditions provides:
(i) the second reactant mixture having a second composition comprising CH₂F₂, WF₆, SF₆, C₄F₈, and O₂,
(ii) a second plasma generation frequency between about 50-2,000 kHz and a third plasma generation frequency between about 20-1000 MHz, and
(iii) a second plasma generation power density between about 18-85 W/cm² at the second plasma generation frequency, and a third plasma generation power density between about 4.9-17 W/cm² at the third plasma generation frequency.

8. The method of claim 7, wherein the second composition further comprises CHF₃ and CH₃F.

9. The method of claim 7, wherein the second composition comprises between about 1-10% SF₆, by volume, excluding any inert gases in the second composition.

10. The method of claim 7, wherein the second composition cycles between composition 2A and composition 2B, wherein composition 2A has a higher concentration of C₄F₈ and CH₂F₂ compared to composition 2B, and wherein composition 2A has a lower concentration of O₂ compared to composition 2B.

11. The method of claim 2, wherein the third set of processing conditions provides:
(i) the third reactant mixture having a third composition comprising CH₂F₂, WF₆, C₄F₈, and O₂,
(ii) a fourth plasma generation frequency between about 50-2,000 kHz and a fifth plasma generation frequency between about 20-100 MHz, and
(iii) a fourth plasma generation power density between about 18-64 W/cm² at the fourth plasma generation frequency, and a fifth plasma generation power density between about 4.9-12.2 W/cm² at the fifth plasma generation frequency.

12. The method of claim 11, wherein the third composition further comprises CHF₃ and CH₃F.

13. The method of claim 2, wherein the first reactant mixture comprises a first composition, the second reactant mixture comprises a second composition, and the third reactant mixture comprises a third composition.

14. The method of claim 13, wherein the first composition has a higher concentration of CH₂F₂ compared to the second composition and the third composition.

15. The method of claim 13, wherein the second composition has a higher concentration of SF₆ than the first composition and the third composition.

16. The method of claim 13, wherein the third composition has a higher concentration of O₂ than the second composition.

17-19. (canceled)

20. The method of claim 1, wherein the third set of processing conditions results in increasing a critical diameter at a bottom of the recessed feature.

21. The method of claim 13, wherein at least one of the following conditions is satisfied:
(1) the first composition comprises a ratio of C:H between about 0.1-3,
(2) the second composition comprises a ratio of C:H between about 0.1-3, and/or
(3) the third composition comprises a ratio of C:H between about 0.2-20.

22. The method of claim 13, wherein at least one of the following conditions is satisfied:
(1) the first composition comprises a ratio of C:W between about 0.1-0.5,
(2) the second composition comprises a ratio of C:W between about 0.1-5, and/or
(3) the third composition comprises a ratio of C:W between about 2-20.

23. The method of claim 1, wherein the first material is silicon oxide and the second material is polysilicon.

24-34. (canceled)
